(19) United States
(12) Patent Application Publication
(10) Pub. No.: US 2013/0291795 A1
(43) Pub. Date: Nov. 7, 2013

(54) THIN FILM DEPOSITION SYSTEM WITH COOLING MODULE

(71) Applicants: Cheng Chia Fang, Taipei City (TW); Cheng Chieh Yang, Taoyuan City (TW)

(72) Inventors: Cheng Chia Fang, Taipei City (TW); Cheng Chieh Yang, Taoyuan City (TW)

(73) Assignee: PINECONE ENERGIES, INC., Taipei City (TW)

(21) Appl. No.: 13/464,595

(22) Filed: May 4, 2012

(51) Int. Cl. C23C 16/46; C23C 16/52; F28F 9/00

(52) U.S. Cl. 118/708; 165/47; 118/725

(57) ABSTRACT

A film deposition apparatus is disclosed. The apparatus comprises: a reaction chamber, a susceptor, a heating module, a driving module, and a cooling module. The susceptor is used for bearing at least one wafer; the heating module is used for heating the wafer; the driving module is used for driving the susceptor to rotate. The cooling module is disposed between the heating module and the driving module. The cooling module is configured to make the temperature distribution between the heating module and the driving module discontinuous.

### FIELD OF THE INVENTION

The present invention is related to a thin film deposition system, particularly to a thin film deposition system with a cooling module.

### BACKGROUND

The film deposition has been widely used for surface processing of various objects, such as jewelry, dishware, tools, molds, and semiconductor devices. Often, on surfaces of metals, alloys, ceramics, and semiconductors, thin films of homogeneous or heterogeneous compositions are formed in order to improve wear resistance, heat resistance, and corrosion resistance.

The techniques of thin film deposition usually are classified into at least two categories, physical vapor deposition (PVD) and chemical vapor deposition (CVD).

Depending on deposition techniques and process parameters, the deposited thin films may have a crystalline, polycrystalline, or amorphous structure. The crystalline thin films often are used as epitaxial layers, which are important for fabrication of integrated circuits. For example, the epitaxial layers are made of semiconductor and doped during formation, resulting in accurate dopant profiles without being contaminated by oxygen and carbon impurities.

One type of chemical vapor deposition (CVD) is called metal-organic chemical vapor deposition (MOCVD). For MOCVD, one or more carrier gases can be used to carry one or more gas-phase reagents or precursors into a reaction chamber that contains one or more substrates (e.g., one or more wafers). The backside of the substrates usually is heated through radio-frequency induction or by a resistor, in order to raise the temperature of the substrates and their ambient temperature. At the elevated temperatures, one or more chemical reactions can occur, converting the one or more reagents or precursors (e.g., in gas phase) into one or more solid products that are deposited onto the surface of the substrates.

For MOCVD, all the gases are mixed and the reactions occur in the reaction chamber. The reaction chamber is usually made of stainless steel or quartz. The inner wall of the reaction chamber usually comprises an inner lining made of quartz or high temperature ceramics. A susceptor is disposed in the chamber for bearing the substrates or wafers. The susceptor is usually made of graphite for being able to absorb the energy from the heater efficiently and raising the temperature to the point for film formation, and is not reactive with respect to the reaction gas. A heating module is usually disposed under the susceptor, and is selectively one of an infrared heating module, a resistance heating module, or a microwave heating module. A driving module is usually disposed under the heating module, and is used for driving the susceptor to rotate.

There is a plurality of cooling channels disposed on the surface of the reaction chamber usually. When the apparatus is operating, water flows in the plurality of cooling channels to prevent the chamber from being overheated. In general, the cooling system is required to prevent people from being burned when touching the surface of the chamber. Consequently, the cooling channels are disposed on the wall, the cap, and even the bottom of the chamber.

However, there is no cooling module for the heating module or the driving module in the current MOCVD apparatus. For a present day MOCVD apparatus, the driving module is not protected, and the cooling of the heating module is not efficient. In view of this, a new cooling module for protecting the driving module and cooling the heating module is needed.

### SUMMARY OF THE INVENTION

The present invention provides a film deposition apparatus, comprising: a reaction chamber; a susceptor disposed in the reaction chamber for bearing at least one wafer; a heating module disposed under the susceptor for heating the at least one wafer; a driving module disposed mostly under the heating module for driving the susceptor to rotate; and a cooling module disposed between the heating module and the driving module, wherein the cooling module is configured to make a temperature distribution between the heating module and the driving module discontinuous.

In one embodiment of the present invention, the driving module comprises: an axle connected to the susceptor; and a motor for driving the susceptor to rotate through the axle.

In one embodiment of the present invention, the driving module further comprises: a driven gear disposed at the axle; and a driving gear mashed with the driven gear and connected to the motor; wherein the motor drove the susceptor to rotate through the driving gear, the driven gear, and the axle.

In one embodiment of the present invention, the driving module comprises: a rotating shell connected to the susceptor and forming a substantially close space, wherein the heating module and the cooling module are disposed in the rotating shell, and the driving module is disposed under the rotating shell; a driven gear connected to the rotating shell; a driving gear mashed with the driven gear; and a motor connected to the driving gear for driving the susceptor to rotate through the driving gear, the driven gear, and the rotating shell.

In one embodiment of the present invention, the cooling module is configured to make a temperature distribution discontinuous in the rotating shell.

In one embodiment of the present invention, a cross-sectional area of the cooling module is greater than a 30% of the cross-sectional area of the rotating shell.

In one embodiment of the present invention, the discontinuous temperature distribution means that a difference of the temperature between the two sides of the cooling module is greater than or equal to 100° C.

In one embodiment of the present invention, an altitude of the cooling module is adjustable.

In one embodiment of the present invention, the cooling module comprises: a cooling body having a tank for containing a refrigerant; a plurality of supporting units for supporting the cooling body, wherein each of the supporting units comprises a channel connected with the tank of the cooling body; and at least one altitude adjusting unit, wherein each of the altitude adjusting unit cooperates with one of the plurality of supporting units and adjusts a length of each support unit in the reaction chamber to adjust the altitude of the cooling module between the heating module and the driving module.

In one embodiment of the present invention, the altitude adjusting module is selectively one of a snake-pipe or at least one O ring with a clamping device.

In one embodiment of the present invention, the altitude adjusting unit is the snake-pipe and the film deposition apparatus further comprises: a microcontroller having a lookup table, wherein the microcontroller generates a first altitude control signal according to a target heating temperature; and a adjusting motor for receiving the first altitude control signal and driving the snake-pipe to shrink or extend according to the first altitude control signal to adjust the cooling module to a first predetermined altitude.

In one embodiment of the present invention, the apparatus further comprises a first temperature sensor disposed between the heating module and the cooling module for generating a first temperature signal.

In one embodiment of the present invention, the microcontroller is electrically coupled to the first temperature sensor for receiving the first temperature signal and monitoring whether the first temperature signal is in a first normal region; when the first temperature signal is out of the first normal region, the microcontroller generates a second altitude control signal and sends the second altitude control signal to the adjusting motor, wherein the adjusting motor drives the snake-pipe to shrink or extend for adjusting the cooling module to a second predetermined altitude according to the second altitude control signal.

In one embodiment of the present invention, the apparatus further comprises a second temperature sensor disposed between the cooling module and the driving module for generating a second temperature signal.

In one embodiment of the present invention, the microcontroller is electrically coupled to the second temperature sensor for receiving the second temperature signal and monitoring whether the second temperature signal is in a second normal region; when the second temperature signal is out of the second normal region, the microcontroller generates a third altitude control signal and sends the third altitude control signal to the adjusting motor, wherein the adjusting motor drives the snake-pipe to shrink or extend for adjusting the cooling module to a third predetermined altitude according to the third altitude control signal.

In one embodiment of the present invention, the film deposition apparatus comprises a reaction chamber, a susceptor, a heating module, a driving module, and the cooling module, wherein the heating module is used for heating at least one material on the susceptor, the driving module is used for driving the susceptor to rotate, the cooling module is disposed between the heating module and the driving module, wherein the cooling module is configured to make a temperature distribution between the heating module and the driving module discontinuous.

In one embodiment of the present invention, the discontinuous temperature distribution means that a difference of the temperature between the two sides of the cooling module is greater than or equal to 100° C.

In one embodiment of the present invention, an altitude of the cooling module is adjustable.

In one embodiment of the present invention, the cooling module comprises: a cooling body having a tank for containing a refrigerant; a plurality of supporting units for supporting the cooling body, wherein each of the supporting units comprises a channel connected with the tank of the cooling body; and at least one altitude adjusting unit, wherein each of the altitude adjusting unit cooperates with one of the plurality of supporting units and adjusts a length of each support unit in the reaction chamber to adjust the altitude of the cooling module between the heating module and the driving module.

In one embodiment of the present invention, the altitude adjusting module is selectively one of a snake-pipe or at least one O ring with a clamping device.

### BRIEF DESCRIPTION OF DRAWINGS

FIG. 1 is a schematic diagram of a conventional MOCVD apparatus.

FIG. 2A is a cross-sectional view in accordance with one embodiment of the present invention.

FIG. 2B is a cross-sectional view in accordance with another embodiment of the present invention.

FIG. 3 is a cross-sectional view of a driving module in accordance with one embodiment of the present invention.

FIG. 4A is a cross-sectional view in accordance with one embodiment of the present invention.

FIG. 4B is a cross-sectional view in accordance with another embodiment of the present invention.

### DETAILED DESCRIPTION

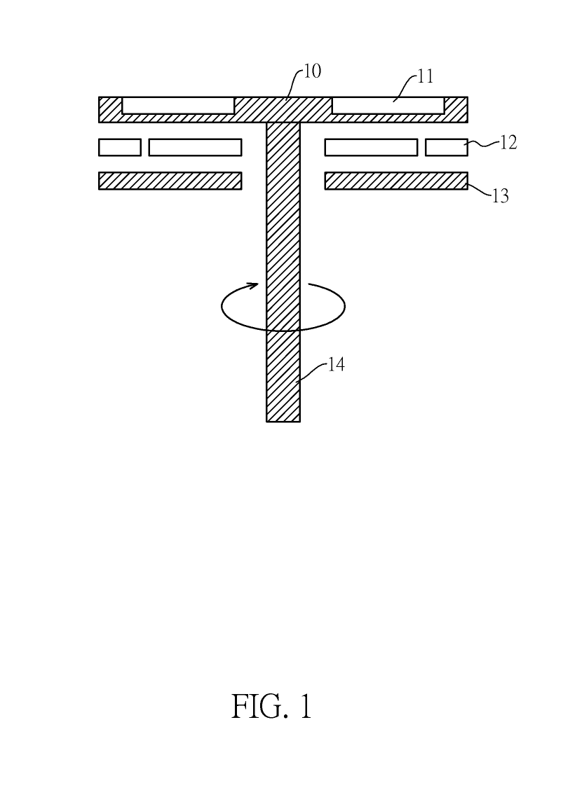

Referring to FIG. 1, there is shown a schematic diagram of a conventional MOCVD apparatus. The reaction chamber of the MOCVD apparatus comprises: a susceptor 10, a heater 12, a heat insulation module 13, and a driving module (not shown). The susceptor 10 is used for bearing at least one wafer 11. The heater 12 is disposed under the susceptor 10 for heating the chamber to the temperature which is needed for the reaction to occur. The heat insulation module 13 is disposed under the heater 12 to cut off the thermal radiation from the heater 12 for protecting the driving module. But the heat insulation module 13 is a passive design; it can only delay an increase of the temperature of the driving module for a finite period of time. Thus, protection of the driving module is limited.

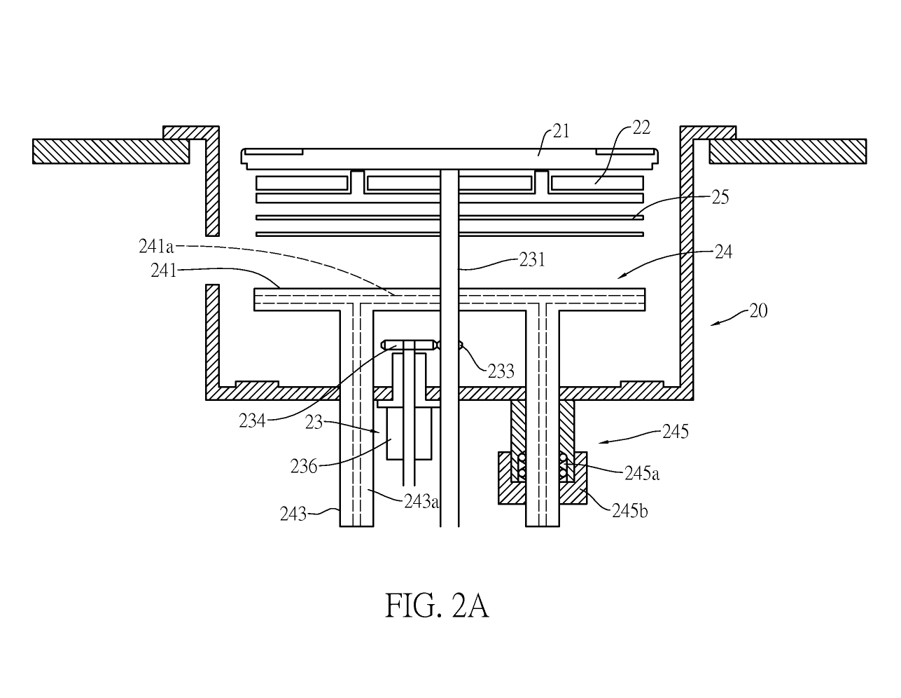

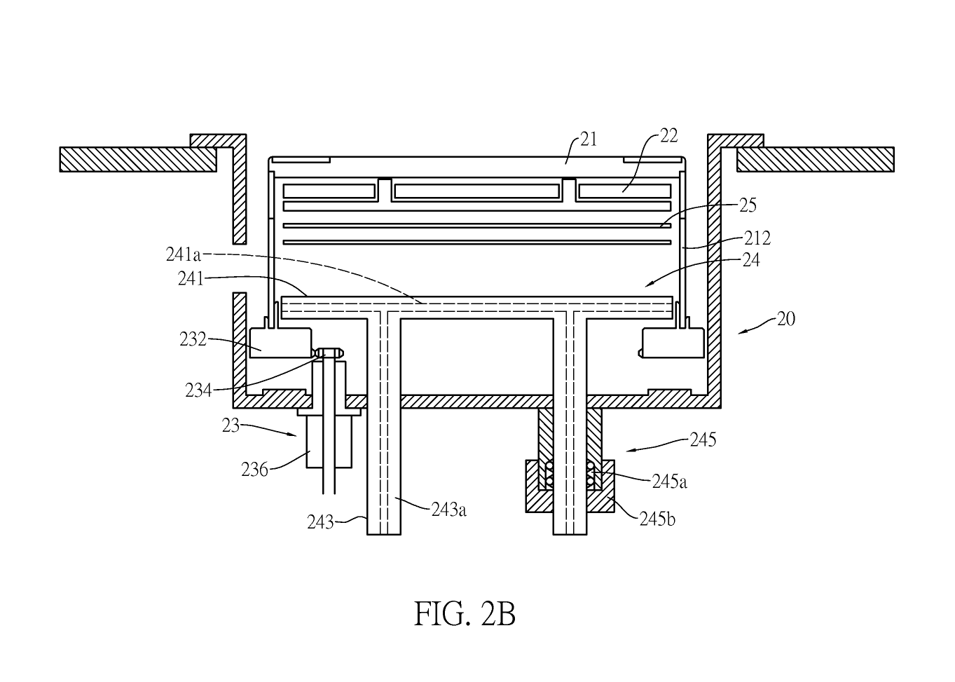

Referring to FIGS. 2A and 2B, there are shown cross-sectional views of two embodiments in accordance with the present invention. The MOCVD apparatus comprises: a reaction chamber 20, a susceptor 21, a heating module 22, a driving module 23, and a cooling module 24.

The susceptor 21 is disposed in the reaction chamber 20 for bearing at least one wafer (not shown). The heating module 22 is disposed under the susceptor 21, and is selectively one of an infrared heating module, a resistance heating module, or a microwave heating module. The driving module 23 is disposed mostly under the heating module 22 for driving the susceptor 21 to rotate. The cooling module 24 is disposed between the heating module 22 and the driving module 23. The cooling module 24 is configured to make the temperature distribution between the heating module 22 and the driving module 23 discontinuous. In one embodiment of the present invention, the discontinuous temperature distribution means that the difference of the temperature between the two sides of the cooling module 24 is great, such as greater than or equal to 100° C. or 200° C.

In one embodiment of the present invention, the altitude of the cooling module 24 is adjustable. The cooling module 24 further comprises: a cooling body 241, a plurality of support units 243, and at least one altitude adjusting unit 245. The cooling body 241 comprises a tank 241a for containing a refrigerant. The plurality of support units 243 are used for supporting the cooling body 241. Each of the support units 243 is provided with a channel 243a connected with the tank 241a in the cooling body 241. Consequently, the refrigerant can flow in to and out of the cooling body 241 through the channels 243a. In one embodiment of the present invention, the refrigerant is selectively one of water or air.

The altitude adjusting unit 245 cooperates with the support unit 243 which adjusts the length of the support unit 243 in the reaction chamber 20 to adjust the altitude of the cooling module 24 between the heating module 22 and the driving module 23.

In one embodiment of the present invention, the altitude adjusting unit 245 comprises at least one O ring 245a and a clamping device 245b. For example, the clamping device 245b is but not limited to a nut.

Before the epitaxial reaction is processed, user can adjust the support unit 243 to an appropriate altitude manually, and then uses the clamping device 245b to clamp the O ring 245a. The O ring 245a is clamped to expand transversely. Consequently, the support unit 243 and the side wall are airtight and fixed.

In one embodiment of the present invention, the cooling module 24 does not contact the driving module 23. The heat insulation effect is greater than the conventional CVD apparatus.

Moreover, in one embodiment of the present invention, the CVD apparatus further comprises a heat insulation module 25. The heat insulation module 25 is disposed between the heating module 22 and the cooling module 24 for improving heat insulation effect.

In one embodiment of the present invention, the driving module 23 comprises: an axle 231, a driven gear 233, a driving gear 234, and a motor 236. The driven gear 233 is disposed at the axle 231; the axle 231 is connected to the susceptor 21; the driving gear 234 is connected to the motor 236; and the driven gear 233 is meshed with the driving gear 234. Consequently, the motor 236 can drive the susceptor 21 to rotate through the driving gear 234, the driven gear 233, and the axle 231, as shown in FIG. 2A.

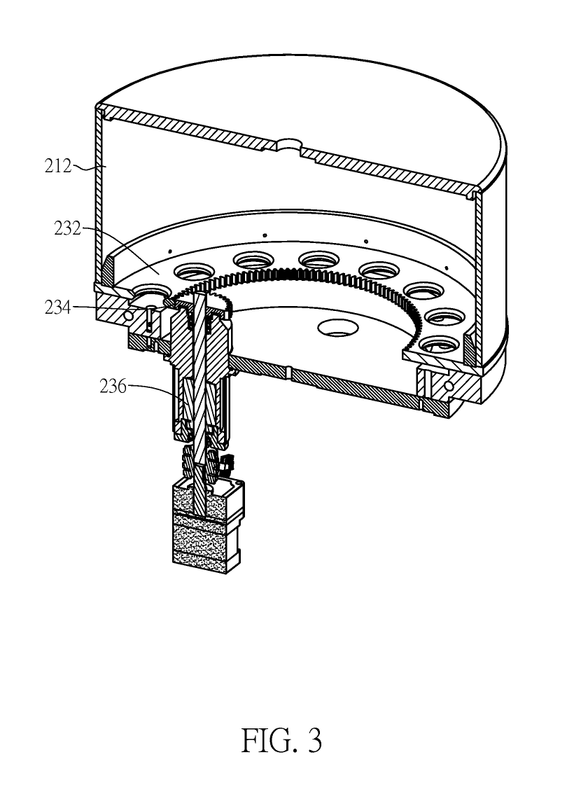

Referring to FIG. 2B and FIG. 3, there are shown a cross-sectional view of one embodiment in accordance with the present invention and a cross-sectional view of a driving module in accordance with one embodiment of the present invention.

In one embodiment of the present invention, the driving module 23 comprises: rotating shell 212, a driven gear 232, a driving gear 234, and a motor 236. The rotating shell 212 is connected to the susceptor 21 and forms a substantially close space. The heating module 22 is disposed in the rotating shell 212 for heating the wafer (not shown). The heating module 22 is selectively one of an infrared heating module, a resistance heating module, or a microwave heating module.

The driven gear 232 is connected to the rotating shell 212; the driving gear 234 is connected to the motor 236; and the driven gear 232 is mashed with the driving gear 234. Consequently, the motor 236 can drive the susceptor 21 to rotate through the driving gear 234, the driven gear 232, and the rotating shell 212, as shown in FIG. 2B and FIG. 3.

In one embodiment of the present invention, the cross-sectional area of the cooling module 24 is greater than or equal to the 30% or 50% of the cross-sectional area of the rotating shell 212.

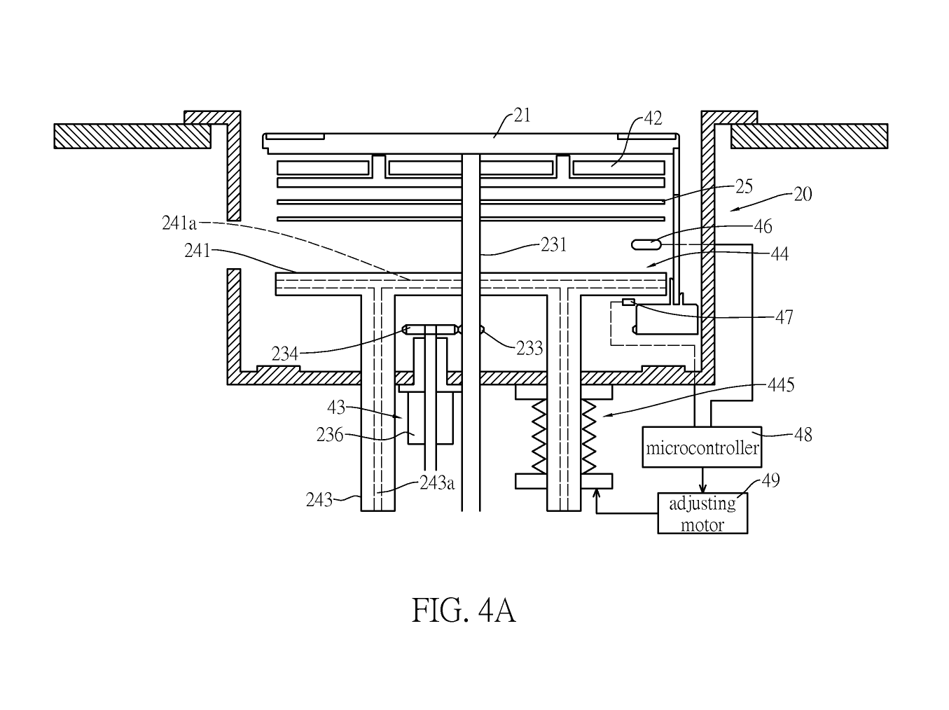

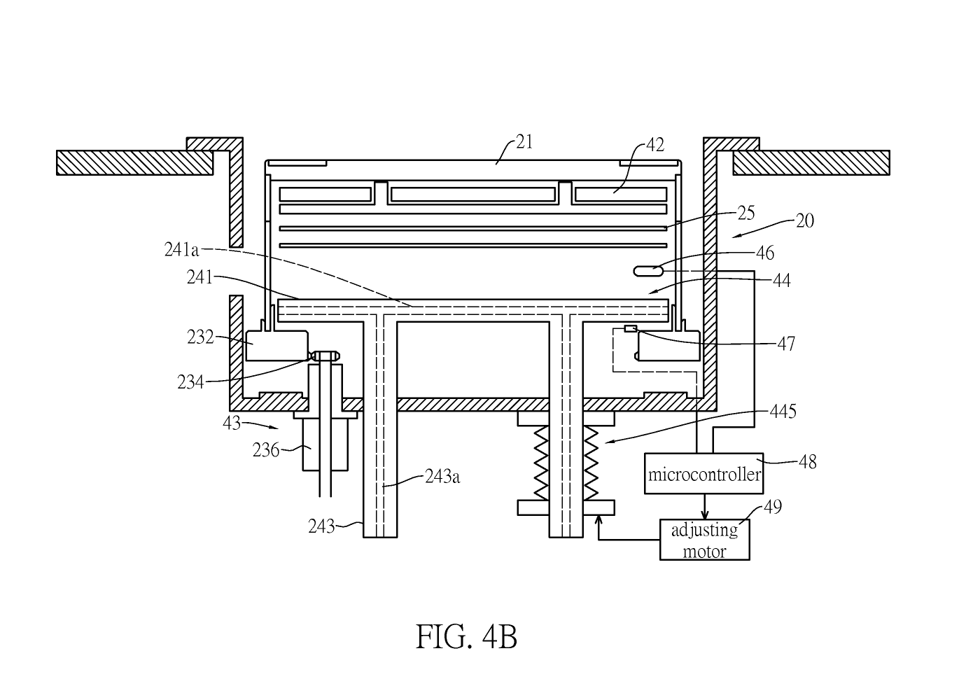

Referring to FIGS. 4A and 4B, there are shown cross-sectional views of two embodiments in accordance with the present invention.

In one embodiment of the present invention, the altitude adjusting module 445 of the cooling module 44 is a snake-pipe which can be greatly compressed and comprises vacuum closure property.

Furthermore, in one embodiment of the present invention, the CVD apparatus further comprises: a microcontroller 48, an adjusting motor 49, a first temperature sensor 46, and a second temperature sensor 47.

The microcontroller 48 comprises a lookup table (not shown), wherein a first altitude control signal (not shown) is generated by the microcontroller 48 when the temperature meets a target temperature.

The adjusting motor 49 is coupled to the microcontroller 48. The adjusting motor 49 drives the snake-pipe 445 to shrink or extend according to the first altitude control signal to adjust the cooling module 44 to a first predetermined altitude.

The first temperature sensor 46 is disposed between the heating module 42 and the cooling module 44 and is electrically coupled to the microcontroller 48 for generating a first temperature signal. The microcontroller 48 monitors whether the first temperature signal is in a first normal region. If the first temperature signal is out of the first normal region, the microcontroller 48 generates a second altitude control signal and sends the second altitude control signal to the adjusting motor 49. The adjusting motor 49 drives the snake-pipe 445 to shrink or extend for adjusting the cooling module 44 to a second predetermined altitude after receiving the second altitude control signal.

The second temperature sensor 47 is disposed between the cooling module 44 and the driving module 43 and is electrically coupled to the microcontroller 48 for generating a second temperature signal. The microcontroller 48 monitors whether the second temperature signal is in a second normal region. If the second temperature signal is out of the second normal region, the microcontroller 48 generates a third altitude control signal and sends the third altitude control signal to the adjusting motor 49. The adjusting motor 49 drives the snake-pipe 445 to shrink or extend for adjusting the cooling module 44 to a third predetermined altitude after receiving the third altitude control signal.

If the predetermined operation temperature of the epitaxial reaction is high (such as 1000° C.), the microcontroller 48 controls the adjusting motor 49 to drive the snake-pipe 445 to shrink. That the cooling module 44 is driven to be away from the heating module 42, in another words be close to the driving module 43, for preventing power consumption. If the predetermined operation temperature of the epitaxial reaction is low (such as 500° C.), the microcontroller 48 controls the adjusting motor 49 to drive the snake-pipe 445 to extend. The cooling module 44 is driven to be close to the heating module 42. If the second temperature sensor 47 senses a temperature that is too high, that means the driving module 43 is in a bad condition. The microcontroller 48 controls the adjusting motor 49 to drive the snake-pipe 445 to shrink. The cooling module 44 is driven to be very close to the driving module 43 for rapidly cooling.

The CVD apparatus of the present invention can adjust the altitude of the cooling module 44 according to the requirement in time for cooling the heating module 42 or the driving module 43, and the heat insulating efficiency of the CVD apparatus is high. Consequently, the defects of the conventional CVD apparatus are overcome.

In one embodiment of the present invention, there is disclosed a cooling module for a film deposition apparatus. The film deposition apparatus is such as but not limited to a CVD apparatus. The film deposition comprises: a reaction chamber, a susceptor, a heating module, a cooling module, and a driving module. The heating module is used for heating material on the susceptor. The material is but not limited to a wafer. The driving module is used to drive the susceptor to rotate. The cooling module is disposed between the heating module and the driving module. The cooling module is configured to make the temperature distribution between the heating module and the driving module discontinuous. In one embodiment of the present invention, the cooling module is configured to make the vertical temperature distribution discontinuous. In one embodiment of the present invention, the discontinuous temperature distribution means that the difference of the temperature between the two sides of the cooling module is greater than or equal to 100° C.

The structure and the variations of the cooling module have been described in the aforementioned embodiments, they won't be repeated here.

The foregoing description is merely embodiments of the present invention and not considered as restrictive. All equivalent variations and modifications in shape, structure, feature, and spirit in accordance with the appended claims may be made without departing from the scope of the invention.

What is claimed is:

1. A film deposition apparatus, comprising:
a reaction chamber;
a susceptor disposed in the reaction chamber for bearing at least one wafer;
a heating module disposed under the susceptor for heating the at least one wafer;
a driving module disposed mostly under the heating module for driving the susceptor to rotate; and
a cooling module disposed between the heating module and the driving module, wherein the cooling module is configured to make a temperature distribution between the heating module and the driving module discontinuous.

2. The apparatus according to claim 1, wherein the driving module comprises:
an axle connected to the susceptor; and
a motor for driving the susceptor to rotate through the axle.

3. The apparatus according to claim 2, wherein the driving module further comprises:
a driven gear disposed at the axle; and
a driving gear mashed with the driven gear and connected to the motor;
wherein the motor drove the susceptor to rotate through the driving gear, the driven gear, and the axle.

4. The apparatus according to claim 1, wherein the driving module comprises:
a rotating shell connected to the susceptor and forming a substantially close space, wherein the heating module and the cooling module are disposed in the rotating shell, and the driving module is disposed under of the rotating shell;
a driven gear connected to the rotating shell;
a driving gear mashed with the driven gear; and
a motor connected to the driving gear for driving the susceptor to rotate through the driving gear, the driven gear, and the rotating shell.

5. The apparatus according to claim 4, wherein the cooling module is configured to make a temperature distribution discontinuous in the rotating shell.

6. The apparatus according to claim 4, wherein a cross-sectional area of the cooling module is greater than a 30% of the cross-sectional area of the rotating shell.

7. The apparatus according to claim 1, wherein the discontinuous temperature distribution means that a difference of the temperature between the two sides of the cooling module is greater than or equal to 100° C.

8. The apparatus according to claim 1, wherein an altitude of the cooling module is adjustable.

9. The apparatus according to claim 8, wherein the cooling module comprises:
a cooling body having a tank for containing a refrigerant;
a plurality of supporting units for supporting the cooling body, wherein each of the supporting units comprises a channel connected with the tank of the cooling body; and
at least one altitude adjusting unit, wherein each of the altitude adjusting unit cooperates with one of the plurality of supporting units and adjusts a length of each support unit in the reaction chamber to adjust the altitude of the cooling module between the heating module and the driving module.

10. The apparatus according to claim 9, wherein the altitude adjusting module is selectively one of a snake-pipe or at least one O ring with a clamping device.

11. The apparatus according to claim 10, wherein the altitude adjusting unit is the snake-pipe and the film deposition apparatus further comprises:
a microcontroller having a lookup table, wherein the microcontroller generates a first altitude control signal according to a target heating temperature; and
a adjusting motor for receiving the first altitude control signal and driving the snake-pipe to shrink or extend according to the first altitude control signal to adjust the cooling module to a first predetermined altitude.

12. The apparatus according to claim 11, further comprising a first temperature sensor disposed between the heating module and the cooling module for generating a first temperature signal.

13. The apparatus according to claim 12, wherein the microcontroller is electrically coupled to the first temperature sensor for receiving the first temperature signal and monitoring whether the first temperature signal is in a first normal region; when the first temperature signal is out of the first normal region, the microcontroller generates a second altitude control signal and sends the second altitude control signal to the adjusting motor, wherein the adjusting motor drives the snake-pipe to shrink or extend for adjusting the cooling module to a second predetermined altitude according to the second altitude control signal.

14. The apparatus according to claim 11, further comprising a second temperature sensor disposed between the cooling module and the driving module for generating a second temperature signal.

15. The apparatus according to claim 14, wherein the microcontroller is electrically coupled to the second temperature sensor for receiving the second temperature signal and monitoring whether the second temperature signal is in a second normal region; when the second temperature signal is out of the second normal region, the microcontroller generates a third altitude control signal and sends the third altitude control signal to the adjusting motor, wherein the adjusting motor drives the snake-pipe to shrink or extend for adjusting the cooling module to a third predetermined altitude according to the third altitude control signal.

16. A cooling module of a film deposition apparatus, wherein the film deposition apparatus comprises a reaction chamber, a susceptor, a heating module, a driving module, and the cooling module, wherein the heating module is used for heating at least one material on the susceptor, the driving module is used for driving the susceptor to rotate, the cooling module is disposed between the heating module and the driving module, wherein the cooling module is configured to make a temperature distribution between the heating module and the driving module discontinuous.

17. The cooling module according to claim 16, wherein the discontinuous temperature distribution means that a difference of the temperature between the two sides of the cooling module is greater than or equal to 100° C.

18. The cooling module according to claim 16, wherein an altitude of the cooling module is adjustable.

19. The cooling module according to claim 16, wherein the cooling module comprises:
a cooling body having a tank for containing a refrigerant;
a plurality of supporting units for supporting the cooling body, wherein each of the supporting units comprises a channel connected with the tank of the cooling body; and
at least one altitude adjusting unit, wherein each of the altitude adjusting unit cooperates with one of the plurality of supporting units and adjusts a length of each support unit in the reaction chamber to adjust the altitude of the cooling module between the heating module and the driving module.

20. The cooling module according to claim 19, wherein the altitude adjusting module is selectively one of a snake-pipe or at least one O ring with a clamping device.
